(19) United States
(12) Patent Application Publication
(10) Pub. No.: US 2026/0261244 A1
(43) Pub. Date: Sep. 3, 2026

(54) VARIABLE GAIN CURRENT MIRROR

(71) Applicant: TEXAS INSTRUMENTS INCORPORATED, Dallas, TX (US)

(72) Inventors: Vanishri HEGDE, Tucson, AZ (US); Paul DAMITIO, Tucson, AZ (US); Bharath Karthik VASAN, Tucson, AZ (US)

(21) Appl. No.: 19/223,261

(22) Filed: May 30, 2025

Related U.S. Application Data
(60) Provisional application No. 63/765,899, filed on Mar. 3, 2025.

(51) Int. Cl. H03F 3/16

(52) U.S. Cl. CPC H03F 3/16

(57) ABSTRACT

A circuit includes: a first transistor; a second transistor; a first resistor; a second resistor; and a third resistor. A control terminal of the second transistor is coupled to a control terminal and a first terminal of the first transistor. A first terminal of the first resistor is coupled to a second terminal of the first transistor. A first terminal of the second resistor is coupled to a second terminal of the second transistor. A first terminal of the third resistor is coupled to a second terminal of the first resistor. A second terminal of the third resistor is coupled to a second terminal of the second resistor.

### CROSS-REFERENCE TO RELATED APPLICATIONS

This application claims priority to U.S. Provisional Application No. 63/765,899, filed March 3, 2025, entitled “Variable Gain Current Mirror Based Buffer,” which is hereby incorporated herein by reference in its entirety.

### TECHNICAL FIELD

The present disclosure relates generally to an electronic system and method, and, in particular embodiments, to a variable gain current mirror.

### BACKGROUND

As an amplifier circuit supports higher output currents and faster transients, larger output devices (transistors) are needed. For some fabrication processes, such as a silicon-germanium (SiGe) process, current gain decreases with temperature. This means larger output devices will have less current gain as temperature increases. As current gain decreases, driving a high resistivity load becomes more difficult and a larger quiescent current (higher power consumption) is needed.

### SUMMARY

In one example, a circuit includes: a first transistor; a second transistor; a first resistor; a second resistor; and a third resistor. The first transistor has a first terminal, a second terminal, and a control terminal. The second transistor has a first terminal, a second terminal, and a control terminal. The control terminal of the second transistor coupled to the control terminal and the first terminal of the first transistor. The first resistor has a first terminal and a second terminal. The first terminal of the first resistor is coupled to the second terminal of the first transistor. The second resistor has a first terminal and a second terminal. The first terminal of the second resistor is coupled to the second terminal of the second transistor. The third resistor has a first terminal and a second terminal. The first terminal of the third resistor is coupled to the second terminal of the first resistor. The second terminal of the third resistor is coupled to the second terminal of the second resistor.

In another example, an amplifier circuit includes: an input terminal; an output terminal; a current regulator coupled to the input terminal; and a variable gain current mirror coupled to the current regulator and the output terminal.

In yet another examples, a circuit includes: a gain stage; a capacitor; and a buffer circuit. The gain stage has a first terminal, a second terminal, and a third terminal. The capacitor has a first terminal and a second terminal. The first terminal of the capacitor is coupled to the third terminal of the gain stage. The buffer circuit has a first terminal and a second terminal. The first terminal of the buffer circuit is coupled to the third terminal of the gain stage. The buffer circuit includes a variable gain current mirror.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an amplifier circuit and a load, in accordance to an embodiment of the present disclosure;

FIG. 2 is a circuit schematic of a buffer circuit, in accordance to an embodiment of the present disclosure;

FIG. 3 is a circuit schematic of another buffer circuit, in accordance to an embodiment of the present disclosure;

FIG. 4 is a graph showing loop gain of an amplifier as a function of frequency, in accordance to an embodiment of the present disclosure;

FIG. 5 is a graph showing output voltage of an amplifier as a function of time, in accordance to an embodiment of the present disclosure;

FIG. 6 is a circuit schematic of current feedback amplifier circuitry and a load, in accordance to an embodiment of the present disclosure;

FIG. 7 is a circuit schematic of voltage feedback amplifier circuitry, in accordance to an embodiment of the present disclosure; and

FIG. 8 is a graph of current gain of a variable gain current mirror as a function of load current for different gain resistor values, in accordance to an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

In an example, a variable gain current mirror includes: a first transistor; a second transistor; a first resistor; a second resistor; and a third resistor. A control terminal of the second transistor is coupled to a control terminal and a first terminal of the first transistor. A first terminal of the first resistor is coupled to a second terminal of the first transistor. A first terminal of the second resistor is coupled to a second terminal of the second transistor. A first terminal of the third resistor is coupled to a second terminal of the first resistor. A second terminal of the third resistor is coupled to a second terminal of the second resistor. In such examples, the third resistor is a gain resistor, and the gain of the variable gain current mirror varies as a function of the resistance of the third resistor and a current through the third resistor. In some embodiments, the variable gain current mirror is part of a buffer circuit. In such examples, the buffer circuit may be part of amplifier circuitry that provides an output voltage and output current responsive to an input voltage or differential input voltage. With a variable gain current mirror, the base (quiescent) current used to drive output transistors of amplifier circuitry can be reduced. Relative to other amplifier or buffer circuitry, use of the variable gain current mirror: reduces overall quiescent current (and related power consumption) without distorting the output signal; supports fast transients; and enables driving a heavier load (e.g., with a load current above a target threshold).

In different examples, one or more variable gain current mirrors may be part of current feedback amplifier circuitry or voltage feedback amplifier circuitry. Such amplifier circuitry, including one or more variable gain current mirrors, may be a standalone integrated circuit (IC) product or may be combined with other circuitry of an IC or IC package. An IC package with the amplifier circuitry may be coupled to external components (e.g., resistors, capacitors, inductors, or IC packages) to form a larger circuit.

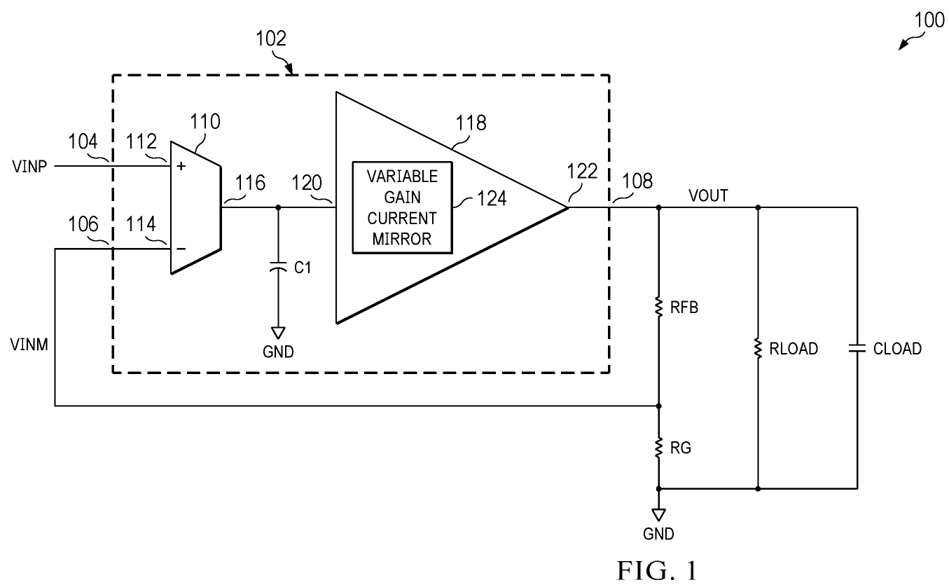

FIG. 1 is a block diagram 100 of an amplifier circuit 102 and a load (resistor RLOAD and capacitor CLOAD), in accordance with an embodiment of the present disclosure. In some embodiments, the amplifier circuit 102 is implemented in an IC and RLOAD and CLOAD are external to the IC. In other embodiments, RLOAD and CLOAD are internal to the IC. In the example of FIG. 1, the circuit schematic 100 also includes resistors RFB and RG, which are external to the amplifier circuit 102 and used to provide a feedback signal to the amplifier circuit 102.

The amplifier circuit 102 has a first terminal 104, a second terminal 106, and a third terminal 108. The first and second terminals 104 and 106 may sometimes be referred to herein as input terminals. The third terminal 108 may sometimes be referred to herein as an output terminal. The amplifier circuit 102 includes a gain stage 110, a capacitor C1, and a buffer circuit 118. The capacitor C1 is a compensation capacitor. The gain stage has a first (non-inverting or “+”) terminal 112, a second (inverting or “-“) terminal 114, and a third terminal 116. The buffer circuit 118 has first terminal 120 and a second terminal 122. The buffer circuit 118 includes a variable gain current mirror 124. Each of the resistor's RFB, RG, and RLOAD has a respective first terminal and a respective second terminal. Each of the capacitors C1 and CLOAD has a respective first terminal and a respective second terminal.

The first terminal 104 of the amplifier circuit 102 is coupled to the first terminal 112 of the gain stage 110. The second terminal 106 of the amplifier circuit 102 is coupled to the second terminal 114 of the gain stage 110. The third terminal 116 of the gain stage 110 is coupled to the first terminal of the capacitor C1 and the first terminal 120 of the buffer circuit 118. The second terminal of the capacitor C1 is coupled to ground or a ground terminal. The second terminal 122 of the buffer circuit 118 is coupled to the third terminal 108 of the amplifier circuit 102. As shown, the third terminal 108 of the amplifier circuit 102 is coupled to the first terminal of the resistor RFB, the first terminal of the resistor RLOAD, and the first terminal of the capacitor CLOAD. The second terminal of the resistor RFB is coupled to the first terminal of the resistor RG and the second terminal 106 of the amplifier circuit 102. The second terminal of the resistor RG, the second terminal of the resistor RLOAD, and the second terminal of the capacitor CLOAD are coupled to ground or a ground terminal.

In operation, the amplifier circuit 102 operates to: receive a first voltage (VINP) at the first terminal 104; receive a second voltage or feedback voltage (VINM) at the second terminal 106; and provide an output voltage (VOUT) at the third terminal 108 responsive to VINP, VINM, the operations of the gain stage 110, and the operations of the buffer circuit 118. The gain stage 110 operates to: receive VINP at the first terminal 112; receive VINM at the second terminal 114; and provide a gain stage result at the third terminal 116 responsive to VINP, VINM, and a gain of the gain stage 110. The capacitor C1 operates to maintain the stability of the amplifier circuit 102. The buffer circuit 118 operates to: receive the gain stage results at the first terminal 120; and provide VOUT at the second terminal 122 responsive to the gain stage results and the operations of the buffer circuit 118.

In some embodiments, relative to other buffer circuits, use of the variable gain current mirror 124: reduces an overall quiescent current (and related power consumption) for the amplifier circuit 102 without causing output signal distortion; supports fast transients; and enables driving a heavier load (e.g., with a load current over a target threshold). The resistors RFB and RG function as a voltage divider, where VINM is the result is the result of the voltage divider. In some embodiments, VINM may be VOUT/2 or another scaling. The load represented by RLOAD and CLOAD receive VOUT and perform a target function responsive to VOUT.

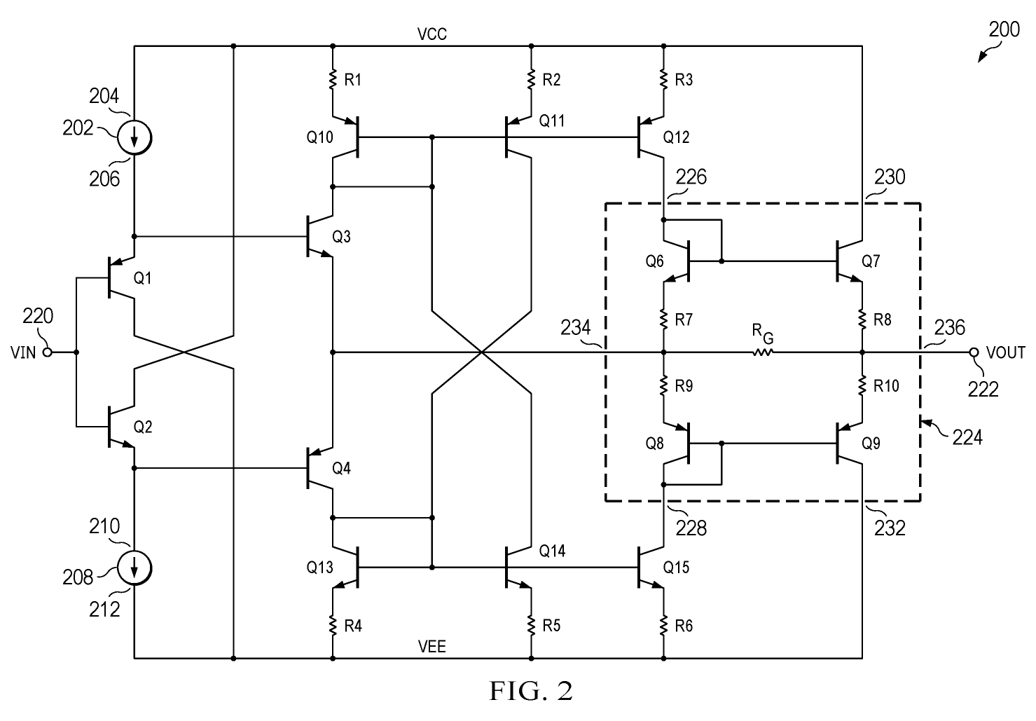

FIG. 2 is a circuit schematic of a buffer circuit 200, in accordance to an embodiment of the present disclosure. The buffer circuit 200 is an example of the buffer circuit 118 in FIG. 1. In the example of FIG. 2, the buffer circuit 200 has a first terminal 220 and a second terminal 222. The first terminal 220 may sometimes be referred to herein as an input terminal. The second terminal 222 may sometimes be referred to herein as an output terminal. The first terminal 220 is an example of the first terminal 120 in FIG. 1. The second terminal 222 is an example of the second terminal 122 in FIG. 1. The buffer circuit 200 includes a first current source 202, a second current source 208, resistors R1 to R10, resistor R_{G}, and transistors Q1 to Q4 and Q6 to Q15 in the arrangement shown. The resistors R7 to R10, the resistor R_{G}, and the transistors Q6 to Q9 are components of a variable gain current mirror 224. The variable gain current mirror 224 is an example of the variable gain current mirror 124 in FIG. 1.

The first current source 202 has a first terminal 204 and a second terminal 206. The second current source 208 has a first terminal 210 and a second terminal 212. Each of the resistors R1 to R10 has a respective first terminal and a respective second terminal. The resistor R_{G} has a first terminal and a second terminal. Each of the transistors Q1 to Q4 and Q6 to Q15 has a respective first terminal (e.g., a collector terminal), a respective second terminal (e.g., an emitter terminal), and a respective control terminal (e.g., a base terminal). The variable gain current mirror 224 has a first terminal 226, a second terminal 228, a third terminal 230, a fourth terminal 232, a fifth terminal 234, and a sixth terminal 236.

The first terminal 220 is coupled to the control terminals of the transistors Q1 and Q2. The second terminal of the transistor Q1 is coupled to the second terminal 206 of the first current source 202 and the control terminal of the transistor Q3. The second terminal of the transistor Q1 is coupled to a second voltage supply (VEE) terminal). The first terminal 204 of the first current source 202 is coupled to a first voltage supply (VCC) terminal. The first terminal of the transistor Q2 is coupled to VCC. The second terminal of the transistor Q2 is coupled to the first terminal 210 of the second current source 208 and the control terminal of the transistor Q4. The second terminal 212 of the second current source 208 is coupled to the VEE terminal. In some examples, current sources such as the first current source 202 and the second current source 208 may be referred to as current regulators. As used herein, a “current regulator” is a current source or a current sink.

The VCC terminal is also coupled to the first terminal of the resistor R1, the first terminal of the resistor R2, the first terminal of the resistor R3, and the third terminal 230 of the variable gain current mirror 224. The second terminal of the resistor R1 is coupled to the second terminal of the transistor Q10. The first terminal of the transistor Q10 is coupled to the first terminal of the transistor Q3, the first terminal of the transistor Q14, and the control terminals of the transistors Q10, Q11, and Q12. The second terminal of the transistor Q3 is coupled to the second terminal of the transistor Q4 and the fifth terminal 234 of the variable gain current mirror 224. The first terminal of the transistor Q4 is coupled to the first terminal of the transistor Q13, the first terminal of the transistor Q11, and the control terminals of the transistors Q13, Q14, and Q15. The second terminal of the transistor Q13 is coupled to the first terminal of the resistor R4. The second terminal of the resistor R4 is coupled to the VEE terminal. The second terminal of the resistor R2 is coupled to the second terminal of the transistor Q11. The second terminal of the transistor Q14 is coupled to the first terminal of the resistor R5. The second terminal of the resistor R5 is coupled to the VEE terminal. The second terminal of the resistor R3 is coupled to the second terminal of the transistor Q12. The first terminal of the transistor Q12 is coupled to the first terminal 226 of the variable gain current mirror 224. The second terminal 228 of the variable gain current mirror 224 is coupled to the first terminal of the transistor Q15. The second terminal of the transistor Q15 is coupled to first terminal of the resistor R6. The second terminal of the resistor R6 is coupled to the VEE terminal. The fourth terminal 232 of the variable gain current mirror 224 is coupled to the VEE terminal. The sixth terminal 236 of the variable gain current mirror 224 is coupled to the second terminal 222 of the buffer circuit 200.

In the example of FIG. 2, the first terminal 226 of the variable gain current mirror 224 is coupled to the first terminal of the transistor Q6 and the control terminals of the transistors Q6 and Q7. The second terminal of the transistor Q6 is coupled to the first terminal of the resistor R7. The second terminal of the resistor R7 is coupled to the fifth terminal 234 of the variable gain current mirror 224, the first terminal of the resistor R9, and the first terminal of the resistor R_{G}. The second terminal of the resistor R9 is coupled to the second terminal of the transistor Q8. The first terminal of the transistor Q8 is coupled to the second terminal 228 of the variable gain current mirror 224 and the control terminals of the transistors Q8 and Q9. The third terminal 230 of the variable gain current mirror 224 is coupled to the first terminal of the transistor Q7. The second terminal of the transistor Q7 is coupled to the first terminal of the resistor R8. The second terminal of the resistor R8 is coupled to the second terminal of the resistor R_{G}, the first terminal of the resistor R10, and the sixth terminal 236 of the variable gain current mirror 224. The second terminal of the resistor R10 is coupled to the second terminal of the transistor Q9. The first terminal of the transistor Q9 is coupled to the fourth terminal 232 of the variable gain current mirror 224. The sixth terminal 236 of the variable gain current mirror 224 is coupled to the second terminal 222 of the buffer circuit 200.

In the example of FIG. 2, the first current source 202, the second current source 208, and the transistors Q1 and Q2 form a pre-driver stage of the buffer circuit 200. The transistors Q3 and Q4 form a reference buffer stage of the buffer circuit 200. The transistors Q10 and Q12 form a first (top) current mirror of the buffer circuit 200. The transistors Q13 and Q15 form a second (bottom) current mirror of the buffer circuit 200. The transistors Q11 and Q14 form trickle current circuitry of the buffer circuit 200 to keep the first and second current mirrors active.

In some embodiments, when the input voltage (VIN) at the first terminal 220 goes high, there is a delta voltage across the resistor R_{G} and a first current mirror (e.g., formed by Q10 and Q12) starts providing base current to the transistor Q7. The current through the transistor Q3 and the current through the transistor Q6 flow through R_{G}, resulting in an increase in V_{BE} for the transistor Q7. With the buffer circuit 200, I_{OUT} at the second terminal 222 responsive to VIN going high is equal to the current through the transistor Q3 + the current through the transistor Q6 + the current through the transistor Q7. In some embodiments, when VIN at the first terminal 220 goes low, there is a delta voltage across the resistor R_{G} and a second current mirror (e.g., formed by Q13 and Q15) starts providing base current to the transistor Q9. The current through the transistor Q4 and the current through the transistor Q8 flow through R_{G}, resulting in an increase in V_{BE} for the transistor Q9. With the buffer circuit 200, I_{OUT} at the second terminal 222 responsive to VIN going low is equal to the current through the transistor Q4 + the current through the transistor Q8 + the current through the transistor Q9. Relative to other buffer circuits, the buffer circuit 200 with the variable gain current mirror 224: reduces the overall quiescent current (and related power consumption) needed from the first current source 202 and the second current source 208 without distorting the output signal; supports fast transients; and enables driving a heavier load (e.g., with a load current above a target threshold).

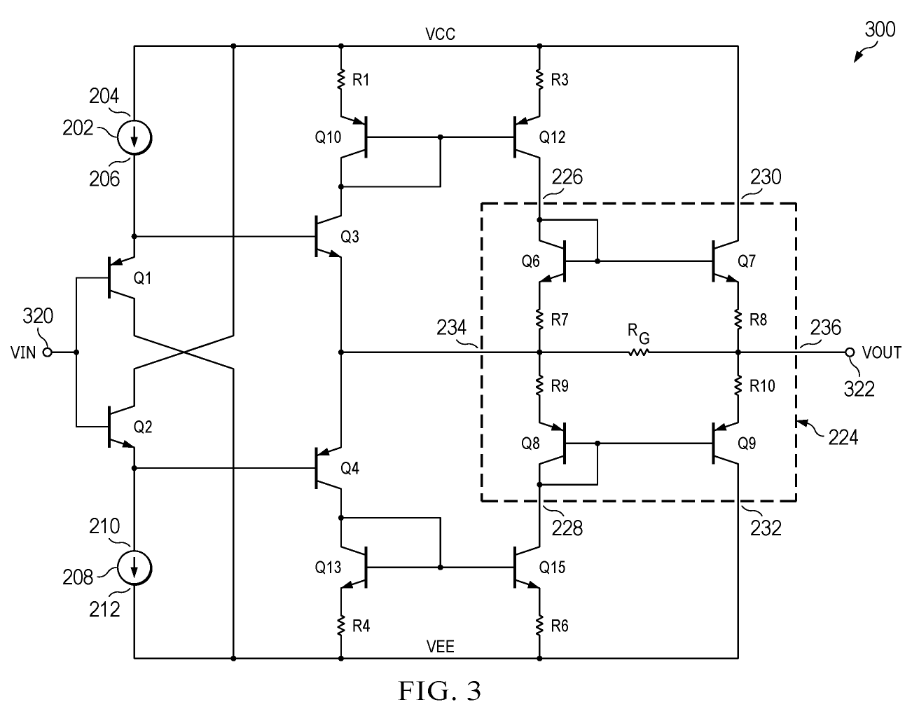

FIG. 3 is a circuit schematic of another buffer circuit 300, in accordance to an embodiment of the present disclosure. The buffer circuit 300 is an example of the buffer circuit 118 in FIG. 1. In the example of FIG. 3, the buffer circuit 300 has a first terminal 320 and a second terminal 322. The first terminal 320 is an example of the first terminal 120 in FIG. 1. The second terminal 322 is an example of the second terminal 122 in FIG. 1. The buffer circuit 300 includes the first current source 202, the second current source 208, resistors R1, R3, R4, R6 to R10, resistor R_{G}, and transistors Q1 to Q4 and Q6 to Q10, Q12, Q13, and Q15 in the arrangement shown. The resistors R7 to R10, the resistor R_{G}, and the transistors Q6 to Q9 are components of the variable gain current mirror 224 described in FIG. 2.

In the example of FIG. 3, the buffer circuit 300 is the same as the buffer circuit 200, except the trickle current circuitry (resistors R2 and R5, and the transistors Q11 and Q13) of the buffer circuit 200 has been omitted. Without the trickle current circuitry, the buffer circuit 300 has a lower quiescent current (lower power consumption) and slower response to transients compared to the buffer circuit 200. For low power applications, the buffer circuit 300 may be preferred over the buffer circuit 200. For fast response applications, the buffer circuit 200 may be preferred over the buffer circuit 300.

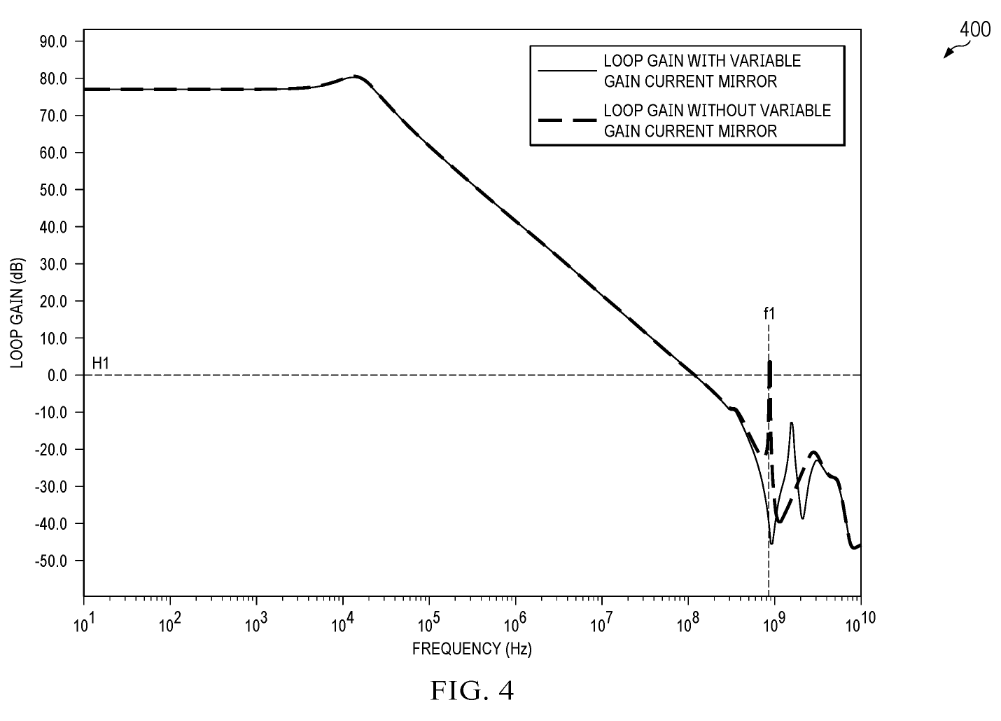

FIG. 4 is a graph 400 showing loop gain of an amplifier as a function of frequency, in accordance to an embodiment of the present disclosure. In the example of FIG. 4, the loop gain of an amplifier is represented for a load current of 50mA. As shown in the graph 400, the loop gain of an amplifier with and without a variable gain current mirror is approximately the same for most frequencies. With the variable gain current mirror, the loop gain decreases and stays below 0dB at higher frequencies, which improves amplifier stability. Without the variable gain current mirror, the loop gain decreases to below 0dB and then increases above 0dB at one or more frequencies (e.g., f1). The loop gain behavior without a variable gain current mirror decreases amplifier stability and may cause oscillations in the amplifier output.

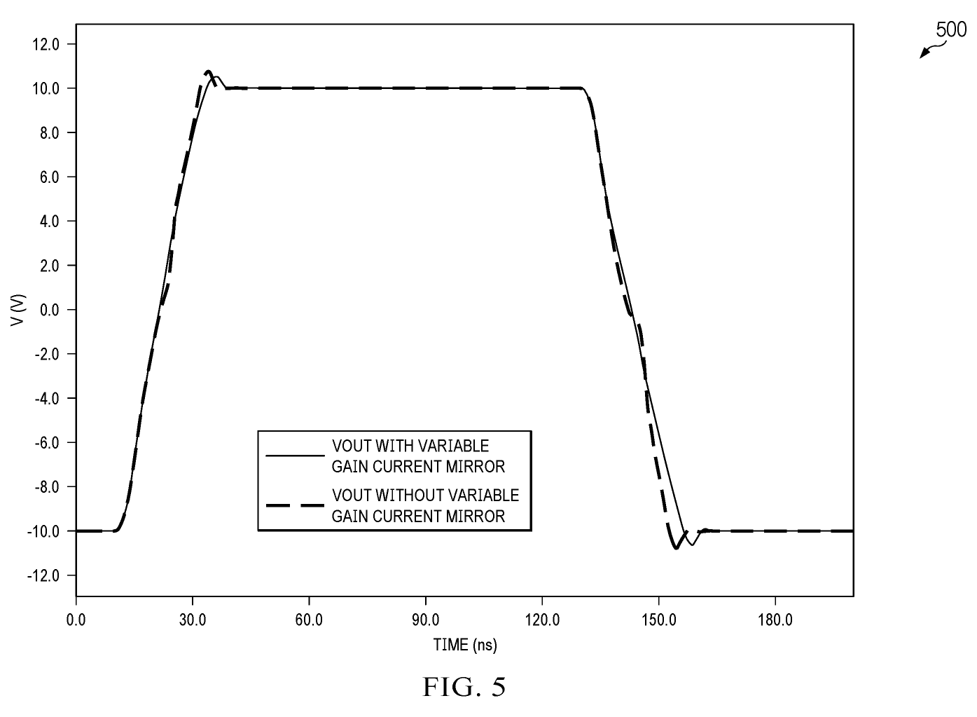

FIG. 5 is a graph 500 showing output voltage of an amplifier as a function of time, in accordance to an embodiment of the present disclosure. In the example of FIG. 5, the output voltage of an amplifier without a variable gain current mirror may transition from low-to-high (e.g., -10V to +10V) and from high-to-low (e.g., +10V to -10V). In the example of FIG. 5, each low-to-high transition and each high-to-low-transition takes about 20ns. The output voltage of an amplifier with a variable gain current mirror may similarly transition from low-to-high (e.g., -10V to +10V) and from high-to-low (e.g., +10V to -10V). When a variable gain current mirror is used, such transitions have improved linearity and less overshoot. Linear transition and overshoot reduction may be important for some amplifier applications.

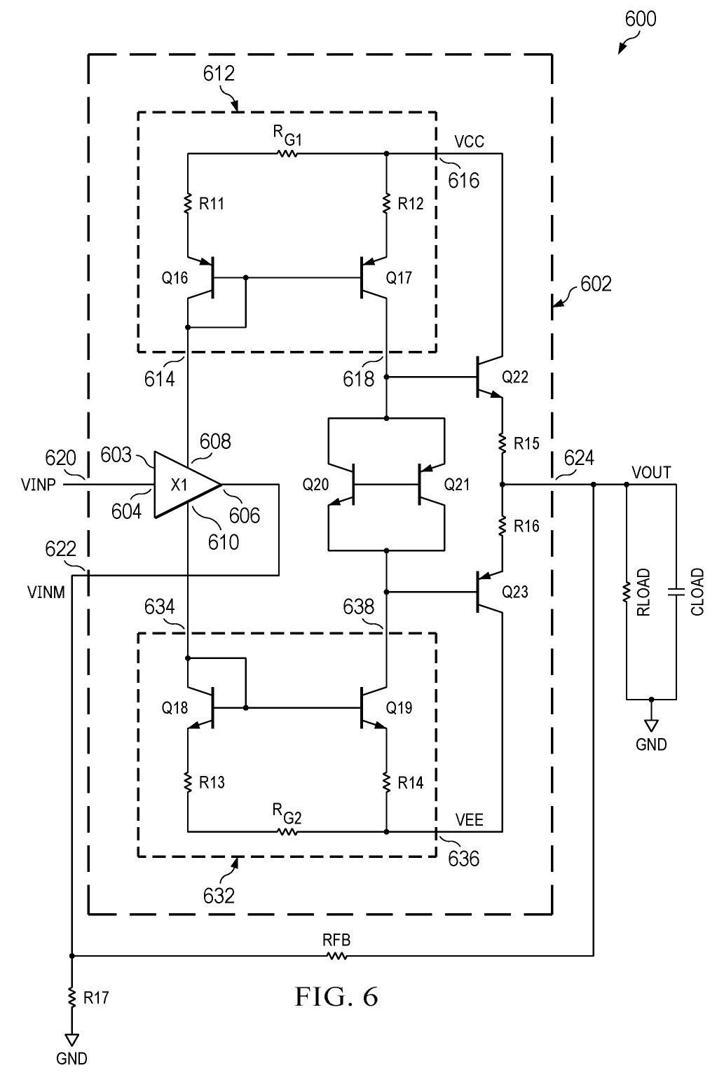

FIG. 6 is a circuit schematic 600 of current feedback amplifier circuitry 602 and a load (RLOAD AND CLOAD), in accordance to an embodiment of the present disclosure. In the example of FIG. 6, the current feedback amplifier circuitry 602 may be part of an IC, while RLOAD and CLOAD are external to the IC. In other embodiments, RLOAD and CLOAD may be part of the IC.

As shown, the current feedback amplifier circuitry 602 has a first terminal 620, a second terminal 622, and a third terminal 624. The current feedback amplifier circuitry 602 includes a buffer circuit 603, resistors R11 to R16, resistors R_{G1} and R_{G2}, and transistors Q16 to Q23 in the arrangement shown. In the example of FIG. 6, the resistors R11, R12, and R_{G1}, and the transistors Q16 and Q17 are components of a first variable gain current mirror 612 of the current feedback amplifier circuitry 602. The resistors R13, R14, and R_{G2}, and the transistors Q18 and Q19 are components of a second variable gain current mirror 632 of the current feedback amplifier circuitry 602. The circuit schematic 600 also includes RFB and R17, which function as a voltage divider to scale VOUT and provide the scaled VOUT as VINM to the second terminal 622 of the current feedback amplifier circuitry 602. In the example of FIG. 6, the resistors RFB and R17 are external to the current feedback amplifier circuitry 602.

The buffer circuit 603 has a first terminal 604, a second terminal 606, a third terminal 608, and a fourth terminal 610. Each of the resistors R11 to R17, and resistors R_{G1} and R_{G2} has a respective first terminal and a respective second terminal. Each of the transistors Q16 to Q23 has a respective first terminal (e.g., a collector terminal), a respective second terminal (e.g., an emitter terminal), and a respective control terminal (e.g., a base terminal). The first variable gain current mirror 612 has a first terminal 614, a second terminal 616, and a third terminal 618. The second variable gain current mirror 632 has a first terminal 634, a second terminal 636, and a third terminal 638.

The first terminal 620 of the current feedback amplifier circuitry 602 is coupled to the first terminal 604 of the buffer circuit 603. The second terminal 622 of the current feedback amplifier circuitry 602 is coupled to the second terminal 606 of the buffer circuit 603. The third terminal 608 of the buffer circuit 603 is coupled to the first terminal 614 of the first variable gain current mirror 612. The first terminal 614 of the first variable gain current mirror 612 is coupled to the first terminal of the transistor Q16, and the control terminals of the transistors Q16 and Q17. The second terminal of the transistor Q16 is coupled to the second terminal of the resistor R11. The first terminal of the resistor R11 is coupled to the second terminal of the resistor R_{G1}. The first terminal of the resistor R_{G1} is coupled to the first terminal of the resistor R12 and the second terminal 616 of the first variable gain current mirror 612. The second terminal of the resistor R12 is coupled to the second terminal of the transistor Q17. The first terminal of the transistor Q17 is coupled to the third terminal 618 of the first variable gain current mirror 612.

The fourth terminal 610 of the buffer circuit 603 is coupled to the first terminal 634 of the second variable gain current mirror 632. The first terminal 634 of the second variable gain current mirror 632 is coupled to the first terminal of the transistor Q18 and the control terminals of the transistors Q18 and Q19. The second terminal of the transistor Q18 is coupled to the first terminal of the resistor R13. The second terminal of the resistor R13 is coupled to the first terminal of the resistor R_{G2}. The second terminal of the resistor R_{G2} is coupled to the second terminal of the resistor R14 and the second terminal 636 of the second variable gain current mirror 632. The first terminal of the resistor R14 is coupled to the second terminal of the transistor Q19. The first terminal of the transistor Q19 is coupled to the third terminal 638 of the second variable gain current mirror 632.

The third terminal 618 of the first variable gain current mirror 612 is coupled to the control terminal of the transistor Q22, the first terminal of the transistor Q20, and the second terminal of the transistor Q21. The third terminal 638 of the second variable gain current mirror 632 is coupled to the control terminal of the transistor Q23, the second terminals of the transistor Q20, and the first terminal of the transistor Q21. The control terminals of the transistors Q20 and Q21 are coupled to each other. The second terminal 616 of the first variable gain current mirror 612 is coupled to the first terminal of the transistor Q22. The second terminal of the transistor Q22 is coupled to the first terminal of the resistor R15. The second terminal of the resistor R15 is coupled to the third terminal 624 of the current feedback amplifier circuitry 602 and the first terminal of the resistor R16. The second terminal of the resistor R16 is coupled to the second terminal of the transistor Q23. The first terminal of the transistor Q23 is coupled to the second terminal 636 of the second variable gain current mirror 632. The third terminal 624 of the current feedback amplifier circuitry 602 is coupled to the first terminals of the resistor RLOAD, the capacitor CLOAD, and the resistor RFB. The second terminals of the resistor RLOAD and the capacitor CLOAD are coupled to ground or a ground terminal. The second terminal of the resistor RFB is coupled to the first terminal of the resistor R17 and the second terminal 622 of the current feedback amplifier circuitry 602. The second terminal of the resistor R17 is coupled to ground or a ground terminal.

In some embodiments, the current feedback amplifier circuitry 602 operates to: receive VINP at the first terminal 620; receive VINM at the second terminal 622; and provide VOUT at the third terminal 624 responsive to VINP, VINM, the operations of the buffer circuit 603; the operations of the first variable gain current mirror 612; the operations of the second variable gain current mirror 632; and related control of the transistors Q22 and Q23. The first variable gain current mirror 612 operates to: receive a first current at the first terminal 614; receive VCC at the second terminal 616; and provide a first (top) mirrored current at the third terminal 618 responsive to the first current and VCC. With the first variable gain current mirror 612, the gain applied to the first current is a function of the value of the resistor R_{G1} and the output current at the third terminal 624 of the current feedback amplifier circuitry 602.

In some embodiments, the second variable gain current mirror 632 operates to: receive a second current at the first terminal 634; receive VEE at the second terminal 636; and provide a second (bottom) mirrored current at the third terminal 638 responsive to the second current and VEE. With the second variable gain current mirror 632, the gain applied to the second current is a function of the value of the resistor R_{G2} and the output current at the third terminal 624 of the current feedback amplifier circuitry 602.

In some embodiments, relative to other current feedback amplifier circuitry, the current feedback amplifier circuitry 602 with the first variable gain current mirror 612 and the second variable gain current mirror 632: enable reduction in the overall quiescent current (e.g., the first and second currents in FIG. 6) without causing distortion to VOUT; support fast transients; and enable driving a heavier load (e.g., with a load current above a target threshold).

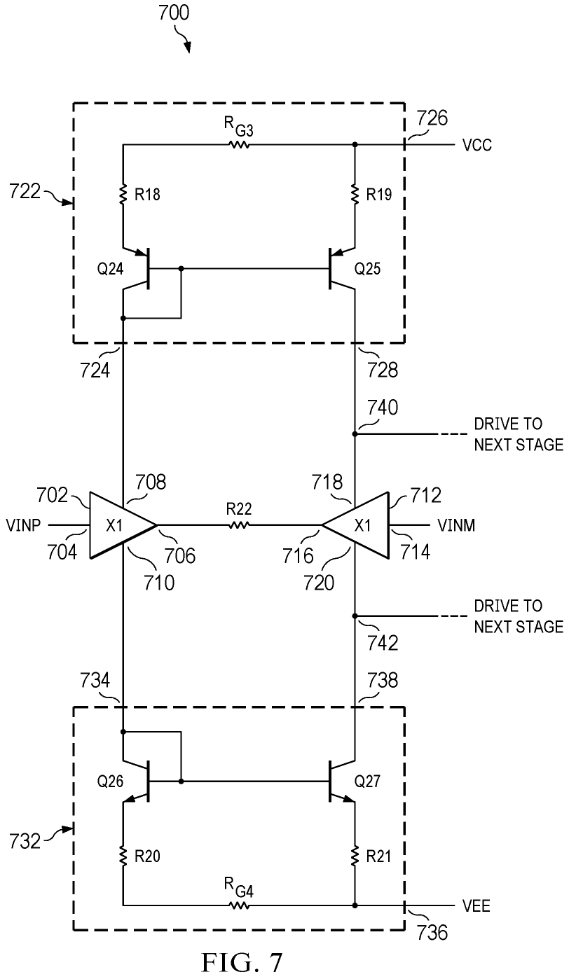

FIG. 7 is a circuit schematic of voltage feedback amplifier circuitry 700, in accordance to an embodiment of the present disclosure. In the example of FIG. 7, the voltage feedback amplifier circuitry 700 may be part of an IC. As shown, the voltage feedback amplifier circuit 700 has terminals 740 and 742 and includes a first buffer circuit 702, a second buffer circuit 712, resistors R18 to R22, resistors R_{G3} and R_{G4}, and transistors Q24 to Q27 in the arrangement shown. The resistors R18, R19, and R_{G3}, and the transistors Q24 and Q25 are components of a first variable gain current mirror 722. The resistors R20, R21, and R_{G4}, and the transistors Q26 and Q27 are components of a second variable gain current mirror 732. The first buffer circuit 702 has a first terminal 704, a second terminal 706, a third terminal 708, and a fourth terminal 710. The second buffer circuit 712 has a first terminal 714, a second terminal 716, a third terminal 718, and a fourth terminal 720. The first variable gain current mirror 722 has a first terminal 724, a second terminal 726, and a third terminal 728. The second variable gain current mirror 732 has a first terminal 734, a second terminal 736, and a third terminal 738. The resistor R22 has a first terminal and a second terminal.

As shown, the second terminal 706 of the first buffer circuit 702 is coupled to the first terminal of the resistor R22. The third terminal 708 of the first buffer circuit 702 is coupled to the first terminal 724 of the first variable gain current mirror 722. The fourth terminal 710 of the first buffer circuit 702 is coupled to the first terminal 734 of the second variable gain current mirror 732. The second terminal 716 of the second buffer circuit 712 is coupled to the second terminal of the resistor R22. The third terminal 718 of the second buffer circuit 712 is coupled to the third terminal 728 of the first variable gain current mirror 722. The fourth terminal 720 of the second buffer circuit 712 is coupled to the third terminal 738 of the second variable gain current mirror 732.

The first terminal 724 of the first variable gain current mirror 722 is coupled to the first terminal of the transistor Q24 and the control terminals of the transistors Q24 and Q25. The second terminal of the transistor Q24 is coupled to the second terminal of the resistor R18. The first terminal of the resistor R18 is coupled to the second terminal of the resistor R_{G3}. The first terminal of the resistor R_{G3} is coupled to the second terminal 726 of the first variable gain current mirror 722 and the first terminal of the resistor R19. The second terminal of the resistor R19 is coupled to the second terminal of the transistor Q25. The first terminal of the transistor Q25 is coupled to the third terminal 728 of the first variable gain current mirror 722.

The first terminal 734 of the second variable gain current mirror 732 is coupled to the first terminal of the transistor Q26 and the control terminals of the transistors Q26 and Q27. The second terminal of the transistor Q26 is coupled to the second terminal of the resistor R20. The first terminal of the resistor R20 is coupled to the second terminal of the resistor R_{G4}. The first terminal of the resistor R_{G4} is coupled to the second terminal 736 of the second variable gain current mirror 732 and the first terminal of the resistor R21. The second terminal of the resistor R21 is coupled to the second terminal of the transistor Q27. The first terminal of the transistor Q27 is coupled to the third terminal 738 of the second variable gain current mirror 732.

The third terminal 728 of the first variable gain current mirror 722 is coupled to the third terminal 718 of the second buffer circuit 712 and the terminal 740 of the voltage feedback amplifier circuitry 700. The third terminal 738 of the second variable gain current mirror 732 is coupled to the fourth terminal 720 of the second buffer circuit 712 and terminal 742 of the voltage feedback amplifier circuitry 700.

In some embodiments, the voltage feedback amplifier circuitry 700 operates to: receive VINP at the first terminal 704 of the first buffer circuit 702; receive VINM at the first terminal 714 of the second buffer circuit 712; provide a first mirrored current at the terminal 740 responsive to a first current at the third terminal 708 of the first buffer circuit 702 and operations of the first variable gain current mirror 722; and provide a second mirrored current at the terminal 742 responsive to a second current at the fourth terminal 710 of the first buffer circuit 702 and operations of the second variable gain current mirror 732. The first mirrored current at the terminal 740 and the second mirror current at the terminal 742 are provided to a next stage of the voltage feedback amplifier circuitry 700. In some embodiments, the next stage includes a second gain stage and/or an output stage.

In some embodiments, the first current at the third terminal 708 of the first buffer circuit 702 is mirrored from the first terminal 724 of the first variable gain current mirror 722 to the third terminal 728 of the first variable gain current mirror 722 responsive to the value of the resistor R_{G3}. The second current at the fourth terminal 710 of the first buffer circuit 702 is mirrored from the first terminal 734 of the second variable gain current mirror 732 to the third terminal 738 of the second variable gain current mirror 732 responsive to the value of the resistor R_{G4}.

In some embodiments, relative to other voltage feedback amplifier circuitry, the voltage feedback amplifier circuitry 700 with the first variable gain current mirror 722 and the second variable gain current mirror 732: enable reduction in the overall quiescent current (e.g., the first and second currents in FIG. 7) without causing distortion; support fast transients; and enable driving a heavier load (e.g., with a load current above a target threshold).

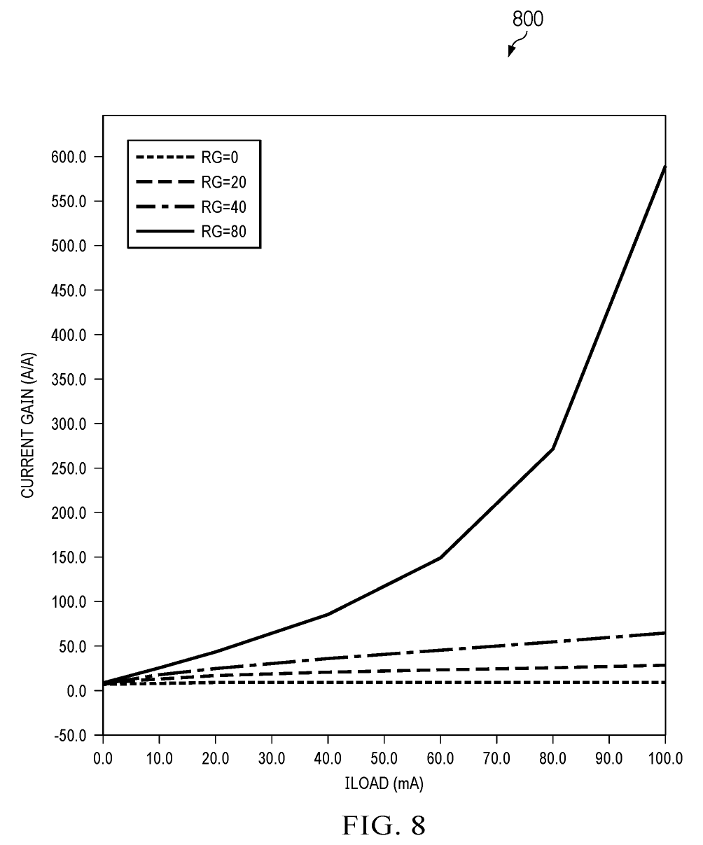

FIG. 8 is a graph 800 of current gain of a variable gain current mirror as a function of load current (ILOAD) for different gain resistor (RG) values (e.g., the R_{G} in FIGS. 2 and 3, R_{G1} in FIG. 6, R_{G2} in FIG. 6, R_{G3} in FIG. 7, or R_{G4} in FIG. 7, according to embodiments of the present disclosure. The example RG values in FIG. 8 are RG = 0ohms, RG = 20ohms, RG = 40ohms, and RG = 80ohms. For RG = 0ohms, the gain stays fixed at approximately 4 as ILOAD increases from 0mA to 100mA. For RG = 20ohms, the gain increases from approximately 4 to 25 as ILOAD increases from 0mA to 100mA. For RG = 40ohms, the gain increases from approximately 4 to 60 as ILOAD increases from 0mA to 100mA. For RG = 80 ohms, the gain increases from approximately 5 to 590 as ILOAD increases from 0mA to 100mA. In different examples, the RG value used in variable gain current mirror may vary.

Example embodiments of the present disclosure are summarized here. Other embodiments can also be understood from the entirety of the specification and the claims filed herein.

Example 1. A circuit including: a first transistor having a first terminal, a second terminal, and a control terminal; a second transistor having a first terminal, a second terminal, and a control terminal, the control terminal of the second transistor coupled to the control terminal and the first terminal of the first transistor; a first resistor having a first terminal and a second terminal, the first terminal of the first resistor coupled to the second terminal of the first transistor; a second resistor having a first terminal and a second terminal, the first terminal of the second resistor coupled to the second terminal of the second transistor; and a third resistor having a first terminal and a second terminal, the first terminal of the third resistor coupled to the second terminal of the first resistor, and the second terminal of the third resistor coupled to the second terminal of the second resistor.

Example 2. The circuit of example 1, further including: a third transistor having a first terminal, a second terminal, and a control terminal; a fourth transistor having a first terminal, a second terminal, and a control terminal, the control terminal of the fourth transistor coupled to the control terminal and the first terminal of the third transistor; a fourth resistor having a first terminal and a second terminal, the first terminal of the fourth resistor coupled to the first terminal of the third resistor, and the second terminal of the fourth resistor coupled to the second terminal of the third transistor; a fifth resistor having a first terminal and a second terminal, the first terminal of the fifth resistor coupled to the second terminal of the third resistor; and the second terminal of the fifth resistor coupled to the second terminal of the fourth transistor.

Example 3. The circuit of one of examples 1 or 2, where the first terminal of the first transistor is coupled to a current regulator, and the first terminal of the second transistor is coupled to a voltage supply terminal.

Example 4. The circuit of one of examples 1 to 3, where the current regulator is a first current regulator, the voltage supply terminal is a first voltage supply terminal, the first terminal of the third transistor is coupled to a second current regulator, and the first terminal of the fourth transistor is coupled to a second voltage supply terminal.

Example 5. The circuit of one of examples 1 to 4, where the first and second transistors are n-type transistors, and where the third and fourth transistors are p-type transistors.

Example 6. The circuit of one of examples 1 to 5, where the first transistor, the second transistor, the first resistor, the second resistor, and the third resistor are components of a variable gain current mirror.

Example 7. The circuit of one of examples 1 to 6, where the variable gain current mirror is part of a buffer circuit.

Example 8. The circuit of one of examples 1 to 7, where the variable gain current mirror is part of an amplifier circuit.

Example 9. The circuit of one of examples 1 to 8, where the variable gain current mirror is a first variable gain current mirror and the amplifier circuit includes a second variable gain current mirror.

Example 10. The circuit of one of examples 1 to 9, where the amplifier circuit is a voltage feedback amplifier circuit.

Example 11. The circuit of one of examples 1 to 10, where the amplifier circuit is a current feedback amplifier circuit.

Example 12. An amplifier circuit including: an input terminal; an output terminal; a current regulator coupled to the input terminal; and a variable gain current mirror coupled to the current regulator and to the output terminal.

Example 13. The amplifier circuit of example 12, where the variable gain current mirror includes: a first transistor having a first terminal, a second terminal, and a control terminal; a second transistor having a first terminal, a second terminal, and a control terminal, the control terminal of the second transistor coupled to the control terminal and the first terminal of the first transistor; a first resistor having a first terminal and a second terminal, the first terminal of the first resistor coupled to the second terminal of the first transistor; a second resistor having a first terminal and a second terminal, the first terminal of the second resistor coupled to the second terminal of the second transistor, the second terminal of the second resistor coupled to the output terminal; and a third resistor having a first terminal and a second terminal, the first terminal of the third resistor coupled to the second terminal of the first resistor, and the second terminal of the third resistor coupled to the output terminal.

Example 14. The amplifier circuit of one of examples 12 or 13, where the variable gain current mirror includes: a third transistor having a first terminal, a second terminal, and a control terminal; a fourth transistor having a first terminal, a second terminal, and a control terminal, the control terminal of the fourth transistor coupled to the control terminal and the first terminal of the third transistor; a fourth resistor having a first terminal and a second terminal, the first terminal of the fourth resistor coupled to the first terminal of the third resistor, and the second terminal of the fourth resistor coupled to the second terminal of the third transistor; a fifth resistor having a first terminal and a second terminal, the first terminal of the fifth resistor coupled to the second terminal of the third resistor; and the second terminal of the fifth resistor coupled to the second terminal of the fourth transistor.

Example 15. The amplifier circuit of one of examples 12 to 14, further including buffer circuitry coupled to the variable gain current mirror, the buffer circuitry including: a pre-driver stage; a reference buffer stage coupled to the pre-driver stage; a first current mirror coupled to the reference buffer stage; and a second current mirror coupled to the reference buffer stage.

Example 16. The amplifier circuit of one of examples 12 to 15, where the buffer circuitry includes trickle current circuitry coupled to the reference buffer stage, the first current mirror, and the second current mirror.

Example 17. The amplifier circuit of one of examples 12 to 16, further including voltage feedback amplifier circuitry coupled to the variable gain current mirror.

Example 18. The amplifier circuit of one of examples 12 to 17, further including current feedback amplifier circuitry coupled to the variable gain current mirror.

Example 19. A circuit including: a gain stage having a first terminal, a second terminal, and a third terminal; a capacitor having a first terminal and a second terminal, the first terminal of the capacitor coupled to the third terminal of the gain stage; and a buffer circuit having a first terminal and a second terminal, the first terminal of the buffer circuit coupled to the third terminal of the gain stage, the buffer circuit including a variable gain current mirror.

Example 20. The circuit of example 19, where the variable gain current mirror includes: a first transistor having a first terminal, a second terminal, and a control terminal; a second transistor having a first terminal, a second terminal, and a control terminal, the control terminal of the second transistor coupled to the control terminal and the first terminal of the first transistor; a first resistor having a first terminal and a second terminal, the first terminal of the first resistor coupled to the second terminal of the first transistor; a second resistor having a first terminal and a second terminal, the first terminal of the second resistor coupled to the second terminal of the second transistor; and a third resistor having a first terminal and a second terminal, the first terminal of the third resistor coupled to the second terminal of the first resistor, and the second terminal of the third resistor coupled to the second terminal of the second resistor.

Example 21. The circuit of one of examples 19 or 20, where the variable gain current mirror includes: a third transistor having a first terminal, a second terminal, and a control terminal; a fourth transistor having a first terminal, a second terminal, and a control terminal, the control terminal of the fourth transistor coupled to the control terminal and the first terminal of the third transistor; a fourth resistor having a first terminal and a second terminal, the first terminal of the fourth resistor coupled to the first terminal of the third resistor, and the second terminal of the fourth resistor coupled to the second terminal of the third transistor; and a fifth resistor having a first terminal and a second terminal, the first terminal of the fifth resistor coupled to the second terminal of the third resistor; and the second terminal of the fifth resistor coupled to the second terminal of the fourth transistor.

Example 22. The circuit of one of examples 19 to 21, further including a fifth transistor and a sixth transistor, the fifth transistor having a first terminal, a second terminal, and a control terminal, the second terminal of the fifth transistor coupled to the first terminal of the third resistor, the sixth transistor having a first terminal, a second terminal, and a control terminal, the second terminal of the sixth transistor coupled to the first terminal of the third resistor.

Example 23. The circuit of one of examples 19 to 22, where the buffer circuit includes: a pre-driver stage; a reference buffer stage coupled to the pre-driver stage; a first current mirror coupled to the reference buffer stage, the first current mirror coupled to the first terminal of the first transistor; and a second current mirror coupled to the reference buffer stage, the second current mirror coupled to the first terminal of the third transistor.

Example 24. The circuit of one of examples 19 to 23, where the buffer circuit includes trickle current circuitry coupled to the reference buffer stage, the first current mirror, and the second current mirror.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT – e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs). For different transistor types, the variable gain of a variable gain current mirror may vary for the same output current and gain resistor value.

References may be made in the claims to a transistor’s control input and its current terminals. In the context of a FET, the control input is the gate, and the current terminals are the drain and source. In the context of a BJT, the control input is the base, and the current terminals are the collector and emitter. The gate, source, and drain of a FET and base, collector, and emitter of a BJT are terminals of the transistor.

Circuits described herein may be reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description may include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter or, if the parameter is zero, a reasonable range of values around zero.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. A circuit comprising:
a first transistor having a first terminal, a second terminal, and a control terminal;
a second transistor having a first terminal, a second terminal, and a control terminal, the control terminal of the second transistor coupled to the control terminal and the first terminal of the first transistor;
a first resistor having a first terminal and a second terminal, the first terminal of the first resistor coupled to the second terminal of the first transistor;
a second resistor having a first terminal and a second terminal, the first terminal of the second resistor coupled to the second terminal of the second transistor; and
a third resistor having a first terminal and a second terminal, the first terminal of the third resistor coupled to the second terminal of the first resistor, and the second terminal of the third resistor coupled to the second terminal of the second resistor.

2. The circuit of claim 1, further comprising:
a third transistor having a first terminal, a second terminal, and a control terminal;
a fourth transistor having a first terminal, a second terminal, and a control terminal, the control terminal of the fourth transistor coupled to the control terminal and the first terminal of the third transistor;
a fourth resistor having a first terminal and a second terminal, the first terminal of the fourth resistor coupled to the first terminal of the third resistor, and the second terminal of the fourth resistor coupled to the second terminal of the third transistor;
a fifth resistor having a first terminal and a second terminal, the first terminal of the fifth resistor coupled to the second terminal of the third resistor; and the second terminal of the fifth resistor coupled to the second terminal of the fourth transistor.

3. The circuit of claim 2, wherein the first terminal of the first transistor is coupled to a current regulator, and the first terminal of the second transistor is coupled to a voltage supply terminal.

4. The circuit of claim 3, wherein the current regulator is a first current regulator, the voltage supply terminal is a first voltage supply terminal, the first terminal of the third transistor is coupled to a second current regulator, and the first terminal of the fourth transistor is coupled to a second voltage supply terminal.

5. The circuit of claim 2, wherein the first and second transistors are n-type transistors, and wherein the third and fourth transistors are p-type transistors.

6. The circuit of claim 1, wherein the first transistor, the second transistor, the first resistor, the second resistor, and the third resistor are components of a variable gain current mirror.

7. The circuit of claim 6, wherein the variable gain current mirror is part of a buffer circuit.

8. The circuit of claim 6, wherein the variable gain current mirror is part of an amplifier circuit.

9. The circuit of claim 8, wherein the variable gain current mirror is a first variable gain current mirror and the amplifier circuit includes a second variable gain current mirror.

10. The circuit of claim 9, wherein the amplifier circuit is a voltage feedback amplifier circuit.

11. The circuit of claim 9, wherein the amplifier circuit is a current feedback amplifier circuit.

12. An amplifier circuit comprising:
an input terminal;
an output terminal;
a current regulator coupled to the input terminal; and
a variable gain current mirror coupled to the current regulator and to the output terminal.

13. The amplifier circuit of claim 12, wherein the variable gain current mirror includes:
a first transistor having a first terminal, a second terminal, and a control terminal;
a second transistor having a first terminal, a second terminal, and a control terminal, the control terminal of the second transistor coupled to the control terminal and the first terminal of the first transistor;
a first resistor having a first terminal and a second terminal, the first terminal of the first resistor coupled to the second terminal of the first transistor;
a second resistor having a first terminal and a second terminal, the first terminal of the second resistor coupled to the second terminal of the second transistor, the second terminal of the second resistor coupled to the output terminal; and
a third resistor having a first terminal and a second terminal, the first terminal of the third resistor coupled to the second terminal of the first resistor, and the second terminal of the third resistor coupled to the output terminal.

14. The amplifier circuit of claim 13, wherein the variable gain current mirror includes:
a third transistor having a first terminal, a second terminal, and a control terminal;
a fourth transistor having a first terminal, a second terminal, and a control terminal, the control terminal of the fourth transistor coupled to the control terminal and the first terminal of the third transistor;
a fourth resistor having a first terminal and a second terminal, the first terminal of the fourth resistor coupled to the first terminal of the third resistor, and the second terminal of the fourth resistor coupled to the second terminal of the third transistor;
a fifth resistor having a first terminal and a second terminal, the first terminal of the fifth resistor coupled to the second terminal of the third resistor; and the second terminal of the fifth resistor coupled to the second terminal of the fourth transistor.

15. The amplifier circuit of claim 14, further comprising buffer circuitry coupled to the variable gain current mirror, the buffer circuitry including:
a pre-driver stage;
a reference buffer stage coupled to the pre-driver stage;
a first current mirror coupled to the reference buffer stage; and
a second current mirror coupled to the reference buffer stage.

16. The amplifier circuit of claim 15, wherein the buffer circuitry includes trickle current circuitry coupled to the reference buffer stage, the first current mirror, and the second current mirror.

17. The amplifier circuit of claim 12, further comprising voltage feedback amplifier circuitry coupled to the variable gain current mirror.

18. The amplifier circuit of claim 12, further comprising current feedback amplifier circuitry coupled to the variable gain current mirror.

19. A circuit comprising:
a gain stage having a first terminal, a second terminal, and a third terminal;
a capacitor having a first terminal and a second terminal, the first terminal of the capacitor coupled to the third terminal of the gain stage; and
a buffer circuit having a first terminal and a second terminal, the first terminal of the buffer circuit coupled to the third terminal of the gain stage, the buffer circuit including a variable gain current mirror.

20. The circuit of claim 19, wherein the variable gain current mirror includes:
a first transistor having a first terminal, a second terminal, and a control terminal;
a second transistor having a first terminal, a second terminal, and a control terminal, the control terminal of the second transistor coupled to the control terminal and the first terminal of the first transistor;
a first resistor having a first terminal and a second terminal, the first terminal of the first resistor coupled to the second terminal of the first transistor;
a second resistor having a first terminal and a second terminal, the first terminal of the second resistor coupled to the second terminal of the second transistor; and
a third resistor having a first terminal and a second terminal, the first terminal of the third resistor coupled to the second terminal of the first resistor, and the second terminal of the third resistor coupled to the second terminal of the second resistor.

21. The circuit of claim 20, wherein the variable gain current mirror includes:
a third transistor having a first terminal, a second terminal, and a control terminal;
a fourth transistor having a first terminal, a second terminal, and a control terminal, the control terminal of the fourth transistor coupled to the control terminal and the first terminal of the third transistor;
a fourth resistor having a first terminal and a second terminal, the first terminal of the fourth resistor coupled to the first terminal of the third resistor, and the second terminal of the fourth resistor coupled to the second terminal of the third transistor; and
a fifth resistor having a first terminal and a second terminal, the first terminal of the fifth resistor coupled to the second terminal of the third resistor; and the second terminal of the fifth resistor coupled to the second terminal of the fourth transistor.

22. The circuit of claim 21, further comprising a fifth transistor and a sixth transistor, the fifth transistor having a first terminal, a second terminal, and a control terminal, the second terminal of the fifth transistor coupled to the first terminal of the third resistor, the sixth transistor having a first terminal, a second terminal, and a control terminal, the second terminal of the sixth transistor coupled to the first terminal of the third resistor.

23. The circuit of claim 22, wherein the buffer circuit includes:
a pre-driver stage;
a reference buffer stage coupled to the pre-driver stage;
a first current mirror coupled to the reference buffer stage, the first current mirror coupled to the first terminal of the first transistor; and
a second current mirror coupled to the reference buffer stage, the second current mirror coupled to the first terminal of the third transistor.

24. The circuit of claim 23, wherein the buffer circuit includes trickle current circuitry coupled to the reference buffer stage, the first current mirror, and the second current mirror.
